(19) United States
(12) Patent Application Publication
(10) Pub. No.: US 2026/0372148 A1
(43) Pub. Date: Nov. 19, 2026

(54) MULTILAYER INTERCONNECTION STRUCTURE AND METHOD FOR FORMING THE SAME

(71) Applicant: STATS ChipPAC Pte. Ltd., Singapore (SG)

(72) Inventors: PeikEng OOI, Singapore (SG); BengYee TEH, Singapore (SG); YiXiang TAY, Singapore (SG)

(21) Appl. No.: 19/679,620

(22) Filed: May 16, 2026

(30) Foreign Application Priority Data
May 16, 2025 (CN) 202510633838.2

(51) Int. Cl. H10W 70/685; H10W 70/06; H10W 70/63; H10W 70/652

(52) U.S. Cl. CPC H10W 70/685; H10W 70/06; H10W 70/635; H10W 70/652

(57) ABSTRACT

A multilayer interconnection structure comprises: a frontside interconnection layer, comprising: a frontside molding base; two frontside conductive pillars formed within and extending through the frontside molding base; a frontside transverse block formed within and extending through the frontside molding base, and the frontside transverse block is between and connected to the two frontside conductive pillars; and a backside interconnection layer laminated on the frontside interconnection layer, comprising: a backside molding base; and a backside conductive pillar formed within and extending through the backside molding base, and wherein the backside conductive pillar is vertically aligned with and coupled to one of the two frontside conductive pillars and the transverse conductive block.

### TECHNICAL FIELD

The present application generally relates to semiconductor technology, and more particularly, to a multilayer interconnection structure and a method for forming a multilayer interconnection structure.

### BACKGROUND OF THE INVENTION

Copper pillars are used to route and transmit signals in molding layers. In some scenarios, the copper pillars may be stacked and connected with each other as multilayer pillars. For example, a first layer of copper pillars which have certain shapes and profiles may be mounted on a temporary or non-temporary substrate and then covered with a molding material. On top of the first layer of copper pillars, a second layer of copper pillars can be further mounted and then be covered with the molding material. The stacking and encapsulation of copper pillars can be repeated to form a more complex interconnection structure.

However, additional redistribution layer (RDL) connections are needed to be formed on one or both of front and back surfaces of the multilayer interconnection structures to connect copper pillars which are separated from each other by the molding material. The RDL connections increase difficulty in routing RDL conductive traces on the front and/or back surfaces of the multilayer interconnection structures.

Therefore, a need exists for an improved multilayer interconnection structure.

### SUMMARY OF THE INVENTION

An objective of the present application is to provide a multilayer interconnection structure which is convenient to route RDL conductive traces.

According to an aspect of the present application, a multilayer interconnection structure is provided. The multilayer interconnection structure comprises: a frontside interconnection layer, comprising: a frontside molding base; at least two frontside conductive pillars formed within and extending through the frontside molding base, and at least two frontside conductive pads formed on a front surface of the frontside molding base, wherein each of the at least two frontside conductive pads is aligned with one of the at least two frontside conductive pillars; a backside interconnection layer laminated on the frontside interconnection layer, comprising: a backside molding base; at least two backside conductive pillars formed within and extending through the backside molding base, and at least two backside conductive pads formed on a back surface of the backside molding base, wherein each of the at least two backside conductive pads is aligned with one of the at least two backside conductive pillars; wherein at least one of the frontside interconnection layer and the backside interconnection layer comprises a transverse conductive block formed within and extending through the corresponding molding base to connect two conductive pillars adjacent to the transverse conductive block in the molding base; and wherein each of the frontside conductive pillars and the backside conductive pillars aligned with and electrically coupled to one of the frontside conductive pillars and the backside conductive pillars and the transverse conductive block.

In another aspect of the present application, a multilayer interconnection structure is provided. The multilayer interconnection structure comprises: a frontside interconnection layer, comprising: a frontside molding base; two frontside conductive pillars formed within and extending through the frontside molding base; a frontside transverse block formed within and extending through the frontside molding base, and the frontside transverse block is between and connected to the two frontside conductive pillars; and a backside interconnection layer laminated on the frontside interconnection layer, comprising: a backside molding base; and a backside conductive pillar formed within and extending through the backside molding base, and wherein the backside conductive pillar is vertically aligned with and coupled to one of the two frontside conductive pillars and the transverse conductive block.

It is to be understood that both the foregoing general description and the following detailed description are exemplary and explanatory only, and are not restrictive of the invention. Further, the accompanying drawings, which are incorporated in and constitute a part of this specification, illustrate embodiments of the invention and together with the description, serve to explain principles of the invention.

### BRIEF DESCRIPTION OF DRAWINGS

The drawings referenced herein form a part of the specification. Features shown in the drawing illustrate only some embodiments of the application, and not of all embodiments of the application, unless the detailed description explicitly indicates otherwise, and readers of the specification should not make implications to the contrary.

FIG. 1 shows a multilayer interconnection structure according to an embodiment of the present application.

FIG. 2 shows a multilayer interconnection structure according to an embodiment of the present application.

FIG. 3 shows a multilayer interconnection structure according to an embodiment of the present application.

FIG. 4 shows a multilayer interconnection structure according to an embodiment of the present application.

FIGS. 5A-5G show a method for forming a multilayer interconnection structure according to an embodiment of the present application.

The same reference numbers will be used throughout the drawings to refer to the same or like parts.

### DETAILED DESCRIPTION OF THE INVENTION

The following detailed description of exemplary embodiments of the application refers to the accompanying drawings that form a part of the description. The drawings illustrate specific exemplary embodiments in which the application may be practiced. The detailed description, including the drawings, describes these embodiments in sufficient detail to enable those skilled in the art to practice the application. Those skilled in the art may further utilize other embodiments of the application, and make logical, mechanical, and other changes without departing from the spirit or scope of the application. Readers of the following detailed description should, therefore, not interpret the description in a limiting sense, and only the appended claims define the scope of the embodiment of the application.

In this application, the use of the singular includes the plural unless specifically stated otherwise. In this application, the use of “or” means “and/or” unless stated otherwise. Furthermore, the use of the term “including” as well as other forms such as “includes” and “included” is not limiting. In addition, terms such as “element” or “component” encompass both elements and components including one unit, and elements and components that include more than one subunit, unless specifically stated otherwise. Additionally, the section headings used herein are for organizational purposes only, and are not to be construed as limiting the subject matter described.

As used herein, spatially relative terms, such as “beneath”, “below”, “above”, “over”, “on”, “upper”, “lower”, “left”, “right”, “vertical”, “horizontal”, “side” and the like, may be used herein for ease of description to describe one element or feature’s relationship to another element(s) or feature(s) as illustrated in the figures. The spatially relative terms are intended to encompass different orientations of the device in use or operation in addition to the orientation depicted in the figures. The device may be otherwise oriented (rotated 90 degrees or at other orientations) and the spatially relative descriptors used herein may likewise be interpreted accordingly. It should be understood that when an element is referred to as being “connected to” or “coupled to” another element, it may be directly connected to or coupled to the other element, or intervening elements may be present.

As aforementioned, additional redistribution layer (RDL) connections on front and back surfaces of multilayer interconnection structures can connect copper pillars formed in a molding material of the multilayer interconnection structures, but such RDL connections increase difficulty in routing RDL conductive traces on the front and/or back surfaces of the multilayer interconnection structures.

To address the above issue, the inventors of the present application proposed a multilayer interconnection structure with conductive pillars which can be connected with each other inside the multilayer interconnection structure. For example, the conductive pillars can be connected with each other via a transverse conductive block at a same layer as the conductive pillars in the multilayer interconnection structure. In some embodiments, the transverse conductive block can be preformed with the conductive pillars connected by the transverse conductive block. In that case, the transverse conductive blocks can provide for transverse connection for conductive pillars and enhance flexibility of trace routing of redistribution layers at the outside of the multilayer interconnection structure.

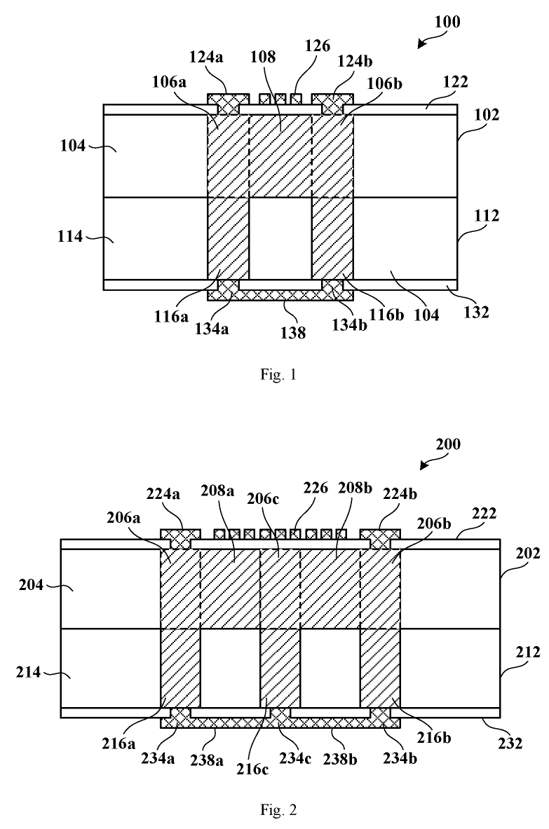

FIG. 1 shows a multilayer interconnection structure 100 according to an embodiment of the present application. The multilayer interconnection structure 100 can be used as an interposer or other similar structures that interconnect certain electronic components and/or substrates mounted at two sides of the multilayer interconnection structure 100. For example, the multilayer interconnection structure 100 can be mounted on a base substrate (not shown), and an electronic component may be further mounted on the multilayer interconnection structure 100 and thus be electrically coupled to the base substrate via the multilayer interconnection structure 100. In another example, the multilayer interconnection structure 100 can be used as a double-sided interconnection structure, with each of its front side and back side mounted with one or more electronic components via redistribution layer (RDL) connections, traces and/or pads, for example.

As shown in FIG. 1, the multilayer interconnection structure 100 is a double layer interconnection structure 100 with a frontside interconnection layer 102 and a backside interconnection layer 112. The frontside interconnection layer 102 and the backside interconnection layer 112 can be connected with each other, for example, by laminating one on the other one using a deposition process or a molding process. In particular, the frontside interconnection layer 102 may have a frontside molding base 104 which can be consisting substantially of an epoxy molding compound (EMC), a polymide compound, or any other suitable dielectric materials. A first frontside conductive pillar 106a and a second frontside conductive pillar 106b are formed within the frontside molding base 104, both of which extend through the frontside molding base 104 to be exposed from both sides of the frontside molding base 104. Furthermore, a transverse conductive block 108 is formed within and extending through the frontside molding base 104 to connect the first and second frontside conductive pillars 106a and 106b which are adjacent to the transverse conductive block 108. As such, the first and second frontside conductive pillars 106a and 106b can be electrically coupled with each other to form a signal path that is transverse to the frontside interconnection layer 102.

It can be appreciated that although in the above example the first and second frontside conductive pillars 106a and 106b are described as two separate “pillars”, it is not required that the two pillars 106a and 106b are formed separately due to the connection by the transverse conductive block 108. For example, the first and second frontside conductive pillars 106a and 106b and the transverse conductive block 108 can be integrally formed as a single piece, e.g., with a size greater than a separate “pillar”, and of a same material such as copper, alumina or other suitable metal or alloy materials. The first and second frontside conductive pillars 106a and 106b and the transverse conductive block 108 which are integrally formed as a single piece can be preformed before assembled with or encapsulated by the corresponding molding base 104. Similarly, in the following embodiments, the conductive pillar(s) and the adjacent conductive blocks which is connected to the conductive pillar(s) and in the same interconnection layer can be formed integrally as a single piece, and can be preformed. In some other examples, the first and second frontside conductive pillars 106a and 106b and the transverse conductive block 108 may be formed as individual pillars or blocks and assembled together later, for example, attached onto the backside interconnection layer 112 in a side-by-side manner, as long as there is no substantive gap between them which may adversely affect the electrical connection.

A frontside insulating layer 122 may be formed on a front surface of the frontside molding base 104 to protect the frontside molding base 104 from external environment and contaminants. Also, the frontside insulating layer 122 provides a substrate where further conductive elements such as redistribution layer (RDL) connections, RDL conductive traces and RDL conductive pads can be formed. For example, a frontside redistribution layer can be formed on the frontside insulating layer 122 and be patterned to form the RDL connections, traces and pads. It can be appreciated that, in order to make the frontside conductive pillars 106a and 106b accessible through the frontside insulating layer 122, two openings can be formed which pass through the frontside insulating layer 122 and expose the frontside conductive pillars 106a and 106b, respectively. When the frontside redistribution layer is formed on the frontside insulating layer 122, the conductive material of the frontside redistribution layer can be filled in the openings and forms RDL conductive pads 124a and 124b which are connected to the respective frontside conductive pillars 106a and 106b. However, as there is no opening that exposes the transverse conductive block 108 in the frontside insulating layer 122, the transverse conductive block 108 may not be directly connected to the RDL layer. In some embodiments, some frontside conductive traces 126 may be formed in the RDL layer which is right above the transverse conductive block 108. Since the frontside conductive pillars 106a and 106b are electrically connected with each other through the transverse conductive block 108, it is not desired to form an RDL connection that electrically connects the frontside RDL conductive pads 124a and 124b with each other. In that case, the frontside conductive traces 126 between the frontside conductive pillars 106a and 106b can extend across a virtual line that connects the frontside RDL conductive pads 124a and 124b, i.e., in a non-transverse direction which is substantially perpendicular to or angled (e.g., an angle of 15 degrees to 90 degrees) from a transverse direction of the transverse conductive block 108. It can be appreciated that the angle between the non-transverse direction and the transverse direction may depend on a design rule for routing conductive wires or traces. In this way, the routing of frontside conductive traces, including the frontside conductive traces 126 on the frontside insulating layer 122, can be more flexible.

The backside interconnection layer 112 has a structure similar as that of the frontside interconnection layer 102, with certain differences. In particular, the backside interconnection layer 112 may have a backside molding base 114 which can be consisting substantially of an epoxy molding compound (EMC), a polymide compound, or any other suitable dielectric materials. The backside molding base 114 may be formed of a material the same as or different from that of the frontside molding base 104. A first backside conductive pillar 116a and a second backside conductive pillar 116b are formed within the backside molding base 114, both of which extend through the backside molding base 114 to be exposed from both sides of the backside molding base 114. The first backside conductive pillar 116a is aligned with the first frontside conductive pillar 106a, while the second backside conductive pillar 116b is aligned with the second frontside conductive pillar 106b. As the first backside conductive pillar 116a is exposed from the front surface of the backside molding base 114 and the first frontside conductive pillar 106a is exposed from the back surface of the frontside molding base 104, and the front surface of the backside molding base 114 is connected to the back surface of the frontside molding base 104, the first frontside conductive pillar 106a can be connected to the first backside conductive pillar 116a at the interface between the frontside and backside interconnection layers 102 and 112. Similarly, the second frontside conductive pillar 106b can be connected to the second backside conductive pillar 116b at the interface between the frontside and backside interconnection layers 102 and 112, thereby forming a vertical electrical path through the entire multilayer interconnection structure 100. It can be appreciated that more frontside conductive pillars and more backside conductive pillars can be formed in the multilayer interconnection structure 100, to provide more vertical electrical paths. However, different from the frontside interconnection layer 102, no transverse conductive block is formed between the backside conductive pillars 116a and 116b which are adjacent to each other. Thus, the first and second backside conductive pillars 116a and 116b are at least isolated from each other at the backside interconnection layer 112, i.e., via the backside molding base 114.

Furthermore, a backside insulating layer 132 may be formed on a back surface of the backside molding base 114 to protect the backside molding base 114 from external environment and contaminants. Also, the backside insulating layer 132 provides a substrate where further conductive elements such as redistribution layer (RDL) connections, RDL conductive traces and RDL conductive pads can be formed. For example, a backside redistribution layer can be formed on the backside insulating layer 132 and be patterned to form the RDL connections, traces and pads. It can be appreciated that, in order to make the backside conductive pillars 116a and 116b accessible through the backside insulating layer 132, two openings can be formed which pass through the backside insulating layer 132 and expose the backside conductive pillars 116a and 116b, respectively. When the backside redistribution layer is formed on the backside insulating layer 132, the conductive material of the backside redistribution layer can be filled in the openings and forms RDL conductive pads 134a and 134b which are connected to the respective backside conductive pillars 116a and 116b. Also, the backside insulating layer 132 can electrically isolate the two backside conductive pads 134a and 134b which are directly connected to the respective backside conductive pillars 116a and 116b.

As aforementioned, since no transverse block is formed between the backside conductive pillars 116a and 116b, no direct transverse electrical path is formed between the backside conductive pillars 116a and 116b. As such, an RDL connection 138 is formed on the backside insulating layer 132, which electrically connects the backside RDL conductive pads 134a and 134b with each other. In this way, a direct transverse electrical path at the back side of the entire multilayer interconnection structure 100 can be established by the transverse RDL connection 138 for the two conductive pillars 116a and 116b.

Although in the embodiment shown in FIG. 1, two frontside conductive pillars 106a and 106b and two backside conducive pillars 116a and 116b are formed in the multilayer interconnection structure 100 and aligned with each other, respectively, more pairs of frontside and backside conductive pillars can be formed similarly.

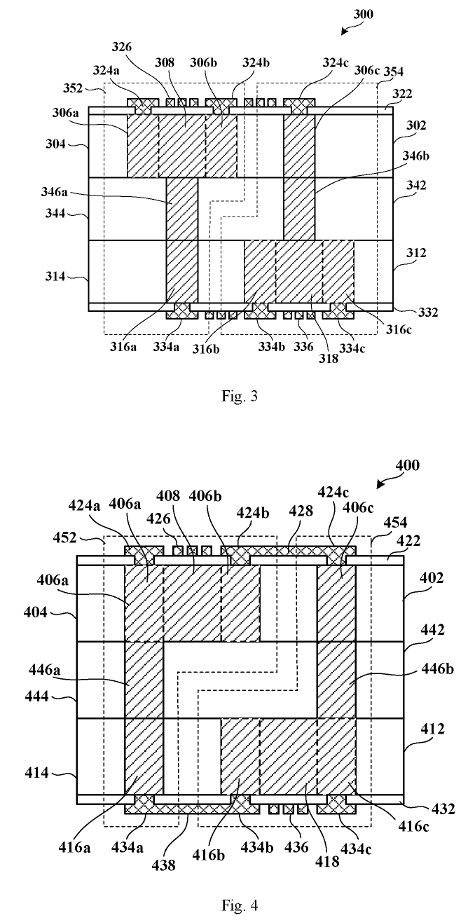

FIG. 2 shows a multilayer interconnection structure 200 according to an embodiment of the present application. Different from the multilayer interconnection structure 100 shown in FIG. 1, more conductive pillars and transverse conductive blocks are integrated within the multilayer interconnection structure 200.

As shown in FIG. 2, the multilayer interconnection structure 200 includes a frontside interconnection layer 202 and a backside interconnection layer 212 which are connected with each other. A first frontside conductive pillar 206a, a second frontside conductive pillar 206b and a third frontside conductive pillar 206c are formed within the frontside molding base 204, and all extend through a frontside molding base 204. Furthermore, in order to connect the three frontside conductive pillars together, a first transverse conductive block 208a is formed within and extending through the frontside molding base 204, which is particularly between the first and third frontside conductive pillars 206a and 206c. Similarly, a second transverse conductive block 208b is formed between the second and third frontside conductive pillars 206b and 206c. As such, an electrical path that is transverse to the frontside interconnection layer 202 can be established between the first and second conductive pillars 206a, 206b. It can be appreciated that more frontside conductive pillars can be connected together similarly in a transverse direction by more transverse conductive blocks in the frontside interconnection layer 202. The first, second and third frontside conductive pillars 206a to 206c and the transverse conductive blocks 208a and 208 can be formed as a single piece, e.g., with a size greater than a separate “pillar”, and of a same material such as copper, alumina or other suitable metal or alloy materials, which can be preformed.

A frontside insulating layer 222 may be formed on a front surface of the frontside molding base 204 to protect the frontside molding base 204 from external environment and contaminants. Also, the frontside insulating layer 222 provides a substrate where further conductive elements such as redistribution layer (RDL) connections, RDL conductive traces and RDL conductive pads can be formed. For example, a frontside redistribution layer can be formed on the frontside insulating layer 222 and later be patterned to form the RDL connections, traces and pads if desired. In the embodiment shown in FIG. 2, two frontside RDL conductive pads 224a and 224b are formed on the frontside insulating layer 222 and pass through the frontside insulating layer 222 at the first and second frontside conductive pillars 206a and 206b. As such the first and second frontside conductive pillars 206a and 206b are connected to the RDL conductive pads 224a and 224b so that they can be connected to external devices through the RDL conductive pads 224a and 224b. However, as no opening is formed at the third frontside conductive pillar 206c, the third frontside conductive pillar 206c is not exposed from the frontside insulating layer 222 and no frontside RDL conductive pad is formed at the third frontside conductive pillars 206c. In some embodiments, since the first and second transverse conductive blocks 208a and 208b are also not exposed from the frontside insulating layer 222 and not be directly connected to the RDL layer, frontside conductive traces 226 may be formed in the RDL layer, which is right above the third conductive pillar 206c, as well as above the transverse conductive block 208a and 208b. Since the frontside conductive pillars 206a to 206c are electrically connected with together through the transverse conductive block 208a and 208b, it is not desired to form an RDL connection that electrically connects them together. In that case, the frontside conductive traces 226 between the frontside conductive pillars 206a and 206b can extend across a virtual line that connects the frontside RDL conductive pads 224a and 224b, i.e., substantially in a non-transverse direction which is perpendicular to or angled from a transverse direction of the transverse conductive blocks 208a and 208b. In this way, the routing of frontside conductive traces, including the frontside conductive traces, on the frontside insulating layer 222 can be more flexible.

The backside interconnection layer 212 has a structure similar as that of the frontside interconnection layer 202, with certain differences. In particular, the backside interconnection layer 212 may have a backside molding base 214 which can be consisting substantially of an epoxy molding compound (EMC), a polymide compound, or any other suitable dielectric materials. The backside molding base 214 may be formed of a material the same as or different from that of the frontside molding base 204. A first backside conductive pillar 216a, a second backside conductive pillar 216b and a third backside conductive pillar 216c are formed within the backside molding base 214, and all extend through the backside molding base 214. The first backside conductive pillar 216a is aligned with and connected to the first frontside conductive pillar 206a, the second backside conductive pillar 216b is aligned with and connected to the second frontside conductive pillar 206b, and the third backside conductive pillar 216c is aligned with and connected to the third frontside conductive pillar 206c, which form three respective vertical electrical paths through the entire multilayer interconnection structure 200. However, different from the frontside interconnection layer 202, no transverse conductive block is formed between the backside conductive pillars 216a and 216c and between the backside conductive pillars 216b and 216c, and thus, the backside conductive pillars 216a to 216c are at least isolated from each other at the backside interconnection layer 212, i.e., via the backside molding base 214.

Furthermore, a backside insulating layer 232 may be formed on a back surface of the backside molding base 214 to protect the backside molding base 214 from external environment and contaminants. Also, the backside insulating layer 232 provides a substrate where further conductive elements such as redistribution layer (RDL) connections, RDL conductive traces and RDL conductive pads can be formed. In particular, three RDL conductive pads 234a, 234b and 234c can be formed which pass through the backside insulating layer 232 and expose the backside conductive pillars 216a, 216b, and 216c, respectively. The backside insulating layer 232 can electrically isolate the backside conductive pads 234a to 234c from each other, but two RDL connections 238a and 238b are formed on the backside insulating layer 232, which electrically connects the backside RDL conductive pads 234a to 234c with each other. In this way, a direct transverse electrical path at the back side of the entire multilayer interconnection structure 200 can be established by the RDL connections 238a and 238b for the conductive pillars 216a to 216b.

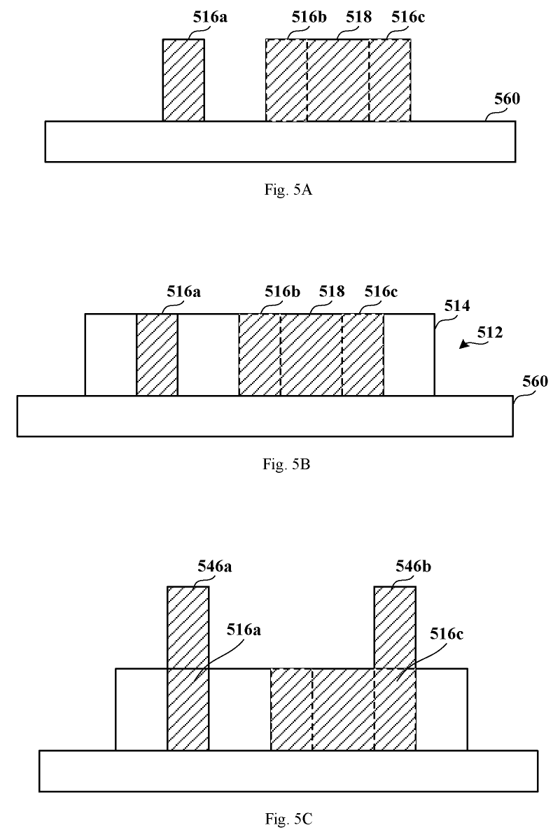

Although FIGS. 1 and 2 show respectively multilayer interconnection structures each having two interconnection layers, more (e.g., three, four or even more) interconnection layers can be laminated together and formed as an integral multilayer connection structure. FIG. 3 shows a multilayer interconnection structure 300 according to an embodiment of the present application, which has a three interconnection layers.

As shown in FIG. 3, the multilayer interconnection structure 300 incudes a frontside interconnection layer 302, a backside interconnection layer 312, and an intermediate interconnection layer 342 between the frontside interconnection layer 302 and the backside interconnection layer 312. Various conductive pillars are formed in the multilayer interconnection structure 300, which form two similar vertical interconnects that are electrically separated from each other at least in the interconnection layers 302, 312 and 342.

In particular, the frontside interconnection layer 302 has a frontside molding base 304, which is covered by a frontside insulating layer 322. A first frontside conductive pillar 306a and a second frontside conductive pillar 306b are formed in the frontside molding base 304, which is connected with each other by a frontside transverse conductive block 308. A first frontside RDL conductive pad 324a and a second frontside RDL conductive pad 324b are formed on the frontside insulating layer 322 and connected to the first and second frontside conductive pillars 306a and 306b, respectively. The backside interconnection layer 312 has a backside molding base 314, which is covered by a backside insulating layer 332. A first backside conductive pillar 316a is formed in the backside molding base 314 and connected to a first backside RDL conductive pad 334a on the backside insulating layer 332.

Similar as the frontside and backside interconnection layers 302 and 312, the intermediate interconnection layer 342 has an intermediate molding base 344 and one or more intermediate conductive pillars. In particular, a first intermediate conductive pillar 346a is formed between and connected to the frontside transverse conductive block 308 and the first backside conductive pillar 316a. It can be seen that the first intermediate conductive pillar 346a is not aligned with any of the first and second frontside conductive pillars 306a and 306b. However, since the first and second frontside conductive pillars 306a and 306b are connected to the frontside transverse conductive block 308, they can be electrically coupled to the intermediate conductive pillar 346a via the frontside transverse conductive block 308 and thus to the first backside conductive pillar 334a. In that case, a first vertical interconnect 352 is formed which provides a vertical electrical path through the multilayer interconnection structure 300. The first vertical interconnect 352 has two frontside RDL conductive pads 324a and 324b at the front side of the multilayer interconnection structure 300, and one backside RDL conductive pad 334a at the back side of the multilayer interconnection structure 300. As such, the first vertical interconnect 352 provides a fan-in or fan-out capability, depending on a signal direction for the vertical interconnect 352.

A second vertical interconnect 354 is also formed in the multilayer interconnection structure 300, which is similar as the first vertical interconnect 352 but has a reversed direction. In particular, the second vertical interconnect 354 has a third frontside conductive pillar 306c in the frontside interconnection layer 302, a second backside conductive pillar 316b, a third backside conductive pillar 316c and a backside transverse conductive block 318 in the backside interconnection layer 312, and a second intermediate conductive pillar 346b in the intermediate interconnection layer 342. The second intermediate conductive pillar 346b is aligned with and connected to the third frontside conductive pillar 306c and the backside transverse conductive block 318, such that another vertical electrical path is formed through the multilayer interconnection structure 300. Similarly, the second vertical interconnect 354 has one frontside RDL conductive pad 324c at the front side of the multilayer interconnection structure 300, and two backside RDL conductive pad 334b and 334c at the back side of the multilayer interconnection structure 300. As such, the second vertical interconnect 354 also provides a fan-in or fan-out capability.

As the first and second vertical interconnects have reversed directions, they can partially overlap with each other in footprint (i.e., slightly offset to each other) to improve the integration of the entire multilayer interconnection structure 300. Also, since the first and second frontside RDL conductive pads 324a and 324b are connected with each other via the frontside transverse conductive block 308, and the second and third backside RDL conductive pads 334b and 334c are connected with each other via the backside transverse conductive block 318, no RDL connection is needed between the frontside RDL conductive pads 324a and 324b, and between the backside RDL conductive pads 334b and 334c. In this way, frontside RDL conductive traces 326 on the frontside insulating layer 322 can be formed between the frontside RDL conductive pads 324a and 324b, or between other adjacent frontside RDL conductive pads such as between the frontside RDL conductive pads 324b and 324c, and backside RDL conductive traces 336 on the backside insulating layer 332 can be formed between the backside RDL conductive pads 334b and 334c, or between other adjacent backside RDL conductive pads such as between the backside RDL conductive pads 334a and 334b. In this way, the routing of the redistribution layers at the outside of the multilayer interconnection structure 300 can be more flexible.

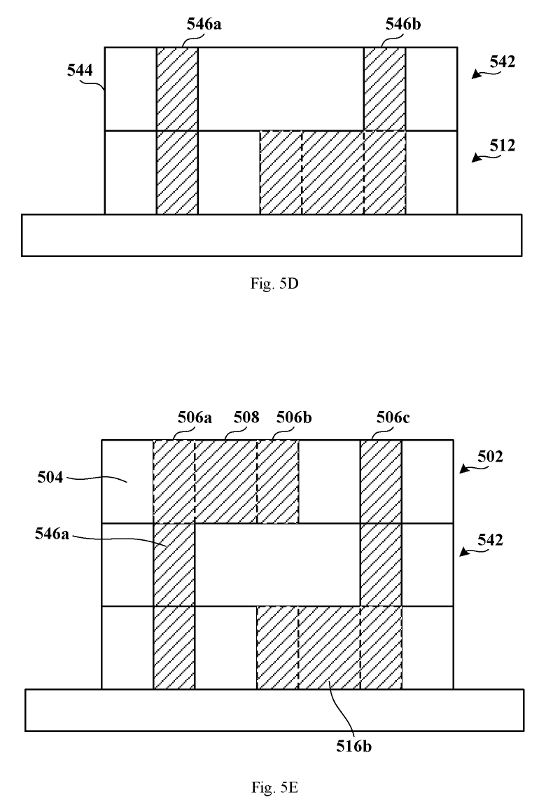

Although in the embodiment shown in FIG. 3, the two vertical interconnects are not electrically coupled with each other, in some other embodiments, vertical interconnects may be electrically coupled with each other using RDL connections. FIG. 4 shows a multilayer interconnection structure 400 according to an embodiment of the present application, which have two vertical interconnects that are electrically coupled with each other.

As shown in FIG. 4, the multilayer interconnection structure 400 incudes a frontside interconnection layer 402, a backside interconnection layer 412, and an intermediate interconnection layer 442 between the frontside interconnection layer 402 and the backside interconnection layer 412. Various conductive pillars are formed in the multilayer interconnection structure 400, which form two similar vertical interconnects that are electrically coupled with each other through a frontside RDL connection 428 on a frontside insulating layer 422 and a backside RDL connection 438 on a backside insulating layer 432.

In particular, the frontside interconnection layer 402 has a frontside molding base 404, which is covered by the frontside insulating layer 422. A first frontside conductive pillar 406a and a second frontside conductive pillar 406b are formed in the frontside molding base 404, which is connected with each other by a frontside transverse conductive block 408. A first frontside RDL conductive pad 424a and a second frontside RDL conductive pad 424b are formed on the frontside insulating layer 422 and connected to the first and second frontside conductive pillars 406a and 406b, respectively. The backside interconnection layer 412 has a backside molding base 414, which is covered by the backside insulating layer 432. A first backside conductive pillar 416a is formed in the backside molding base 414 and connected to a first backside RDL conductive pad 434a on the backside insulating layer 432. The intermediate interconnection layer 442 has an intermediate molding base 444 and one or more intermediate conductive pillars. In particular, a first intermediate conductive pillar 446a is formed between and connected to the first frontside conductive pillar 406a and the first backside conductive pillar 416a. The first intermediate conductive pillar 446 is specifically aligned with the first frontside conductive pillar 406a and the first backside conductive pillar 416a, to provide a vertical electrical path through the multilayer interconnection structure 400. The first vertical interconnect 452 has two frontside RDL conductive pads 424a and 424b at the front side of the multilayer interconnection structure 400, and one backside RDL conductive pad 434a at the back side of the multilayer interconnection structure 400. As such, the first vertical interconnect 452 provides a fan-in or fan-out capability.

A second vertical interconnect 454 is also formed in the multilayer interconnection structure 400, which is similar as the first vertical interconnect 452 but has a reversed direction. In particular, the second vertical interconnect 454 has a third frontside conductive pillar 406c in the frontside interconnection layer 402, a second backside conductive pillar 416b, a third backside conductive pillar 416c and a backside transverse conductive block 418 in the backside interconnection layer 412, and a second intermediate conductive pillar 446b in the intermediate interconnection layer 442. The second intermediate conductive pillar 446b is aligned with and connected to the third frontside conductive pillar 406c and the third backside conductive pillar 416c, such that another vertical electrical path is formed through the multilayer interconnection structure 400. Similarly, the second vertical interconnect 454 has one frontside RDL conductive pad 424c at the front side of the multilayer interconnection structure 400, and two backside RDL conductive pad 434b and 434c at the back side of the multilayer interconnection structure 400. As such, the second vertical interconnect 454 also provides a fan-in or fan-out capability.

As the first and second vertical interconnects 452 and 454 are electrically separated from each other in the frontside interconnection layer 402, the frontside RDL connection 428 can be formed to electrically connect the frontside RDL conductive pad 424b of the first vertical interconnect 452 and the frontside RDL conductive pad 424c of the second vertical interconnect 454. Similarly, in some optional embodiments, the first and second vertical interconnects 452 and 454 can be further electrically coupled with each other at the back side of the multilayer interconnection structure 400. In particular, the backside RDL connection 438 can be formed to electrically connect the backside RDL conductive pad 434a of the first vertical interconnect 452 and the backside RDL conductive pad 434b of the second vertical interconnect 454. In this way, frontside RDL conductive traces 426 can be formed on the frontside insulating layer 422 and between the frontside RDL conductive pads 424a and 424b, and backside RDL conductive traces 436 can be formed on the backside insulating layer 432 and between the backside RDL conductive pads 434b and 434c. In this way, the routing of the redistribution layers at the outside of the multilayer interconnection structure 400 can be more flexible.

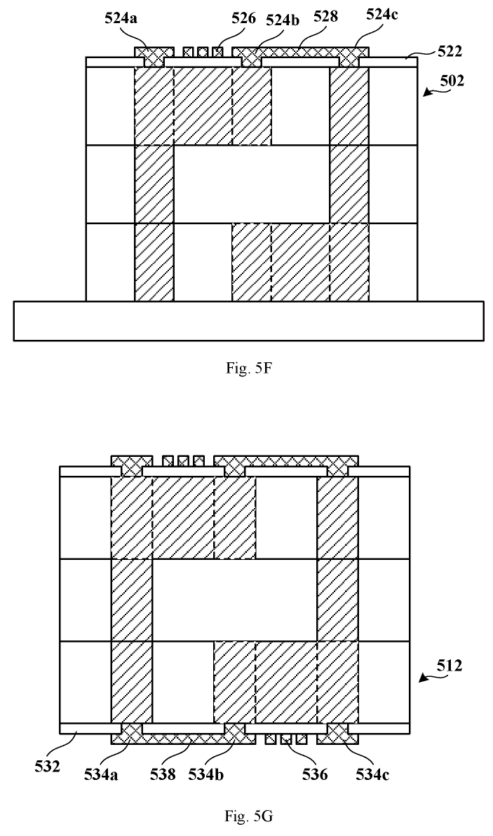

FIGS. 5A-5G show a method for forming a multilayer interconnection structure according to an embodiment of the present application.

As show in FIG. 5A, certain backside conductive pillars 516a, 516b and 516c and a backside transverse conductive block 518 are mounted on a carrier 560 such as a platform or a tape. The backside conductive pillars 516b, 516c and the backside transverse conductive block 518 are integrally formed as a single piece so that they can be mounted on the carrier 560 together. All of the backside conductive pillars 516a, 516b and 516c and the backside transverse conductive block 518 are preformed with certain shapes and sizes so they can be mounted on the carrier 560 at predetermined positions.

Next, as shown in FIG. 5B, a molding compound is formed on the carrier 560 to encapsulate the backside conductive pillars 516a, 516b and 516c and the backside transverse conductive block 518. An excess portion of the molding compound can be grinded or otherwise removed to expose respective front surfaces of the backside conductive pillars 516a, 516b and 516c and the backside transverse conductive block 518, leaving the remaining portion as a backside molding base 514. As such, a backside interconnection layer 512 can be formed.

Next, as shown in FIG. 5C, two intermediate conductive pillars 546a and 546b can be stacked on and connected to the first and third backside conductive pillars 516a and 516c, respectively. And then a molding compound is formed on the backside interconnection layer 512 to encapsulate the intermediate conductive pillars 546a and 546b, as an intermediate molding base 544 shown in FIG. 5D. As such, an intermediate interconnection layer 542 is formed.

One or more interconnection layers can be further formed. As shown in FIG. 5E, a frontside interconnection layer 502 is formed on the intermediate interconnection layer 542. The frontside interconnection layer 502 includes a frontside molding base 504, a first, second and third frontside conductive pillars 506a, 506b and 506c, and a frontside transverse conductive block 508 which is formed between and connected to the first and second frontside conductive pillars 506a and 506b. The first frontside conductive pillar 506a is aligned with and connected to the first intermediate conductive pillar 546a. Due to the separation by the molding materials in the frontside, intermediate and backside molding bases, the second frontside conductive pillar 506b is electrically isolated from the second backside conductive pillar 516b.

Next, as shown in FIG. 5F, a frontside insulating layer 522 can be formed on a front surface of the frontside interconnection layer 502. Afterwards, the frontside insulating layer 522 can be patterned, a frontside RDL layer can be formed and patterned, to form frontside RDL conductive pads 524a, 524b and 524c, a frontside RDL connection 528 connecting the second and third frontside RDL conductive pads 524b and 524c, and frontside RDL conductive traces 526 between the first and second frontside RDL conductive pads 524a and 524b.

Next, as shown in FIG. 5G, the entire multilayer interconnection structure can be flipped over. Then a backside insulating layer 532 can be formed on a back surface of the backside interconnection layer 512. Afterwards, the backside insulating layer 532 can be patterned, a backside RDL layer can be formed and patterned, to form backside RDL conductive pads 534a, 534b and 534c, a backside RDL connection 538 connecting the first and second backside RDL conductive pads 534a and 534b, and frontside RDL conductive traces 536 between the second and third backside RDL conductive pads 534b and 534c. In this way, the multilayer interconnection structure can be formed.

As can be seen from the above embodiments, the transverse conductive block which is formed in an interconnection layer of the multilayer interconnection structure and between two conductive pillars can play a role similar as a transverse RDL conductive connection which is on an outside surface of the multilayer interconnection structure, and thus, no such transverse RDL conductive connection is needed at a position vertically aligned with the transverse conductive block. As such, the space on the corresponding insulating layer can be used for routing of RDL conductive traces.

The discussion herein included numerous illustrative figures that showed various portions of a multilayer interconnection structure. For illustrative clarity, such figures did not show all aspects of each example assembly. Any of the example assemblies and/or methods provided herein may share any or all characteristics with any or all other assemblies and/or methods provided herein.

Various embodiments have been described herein with reference to the accompanying drawings. It will, however, be evident that various modifications and changes may be made thereto, and additional embodiments may be implemented, without departing from the broader scope of the invention as set forth in the claims that follow. Further, other embodiments will be apparent to those skilled in the art from consideration of the specification and practice of one or more embodiments of the invention disclosed herein. It is intended, therefore, that this application and the examples herein be considered as exemplary only, with a true scope and spirit of the invention being indicated by the following listing of exemplary claims.

1. A multilayer interconnection structure, comprising:
a frontside interconnection layer, comprising:
a frontside molding base; and
at least two frontside conductive pillars formed within and extending through the frontside molding base,
at least two frontside conductive pads formed on a front surface of the frontside molding base, wherein each of the at least two frontside conductive pads is aligned with one of the at least two frontside conductive pillars;
a backside interconnection layer laminated on the frontside interconnection layer, comprising:
a backside molding base; and
at least two backside conductive pillars formed within and extending through the backside molding base, and
at least two backside conductive pads formed on a back surface of the backside molding base, wherein each of the at least two backside conductive pads is aligned with one of the at least two backside conductive pillars;
wherein at least one of the frontside interconnection layer and the backside interconnection layer comprises a transverse conductive block formed within and extending through the corresponding molding base to connect two conductive pillars adjacent to the transverse conductive block in the molding base; and
wherein each of the frontside conductive pillars and the backside conductive pillars aligned with and electrically coupled to one of the frontside conductive pillars and the backside conductive pillars and the transverse conductive block.

2. The multilayer interconnection structure of claim 1, further comprising:
a frontside insulating layer formed on the front surface of the frontside molding base, and for electrically isolating the at least two frontside conductive pads; and
a backside insulating layer formed on the back surface of the backside molding base, and for electrically isolating the at least two backside conductive pads.

3. The multilayer interconnection structure of claim 2, further comprising:
at least one transverse conductive connection formed on at least one of the frontside insulating layer and the backside insulating layer to connect two conductive pillars isolated by the insulating layer.

4. The multilayer interconnection structure of claim 3, further comprising:
at least one non-transverse conductive trace formed on at least one of the frontside insulating layer and the backside insulating layer, wherein the at least one non-transverse conductive trace extends in a direction perpendicular to or angled from that of the at least one transverse conductive connection.

5. The multilayer interconnection structure of claim 3, wherein the transverse conductive block is formed in one of the frontside interconnection layer and the backside interconnection layer, and the transverse conductive connection is formed on the insulating layer on the other of the frontside interconnection layer and the backside interconnection layer.

6. The multilayer interconnection structure of claim 1, wherein the transverse conductive block is integrally formed with the two conductive pillars adjacent thereto as a single piece.

7. The multilayer interconnection structure of claim 1, further comprising:
an intermediate interconnection layer formed between the frontside interconnection layer and the backside interconnection layer, and comprising:
an intermediate molding base; and
at least two intermediate conductive pillars formed within and extending through the intermediate molding base; and
wherein each of the at least two intermediate conductive pillars is aligned with and electrically coupled to two of the conductive pillars and the backside conductive pillars and the transverse conductive block that are aligned with each other.

8. The multilayer interconnection structure of claim 7, wherein the frontside interconnection layer comprises a frontside transverse conductive block formed within and extending through the frontside molding base, and the backside interconnection layer comprises a backside transverse conductive block formed within and extending through the backside molding base, and wherein the frontside transverse conductive block is isolated from the backside transverse conductive block by the intermediate molding base.

9. The multilayer interconnection structure of claim 1, wherein the transverse conductive block and the two conductive pillars adjacent to the transverse conductive block are preformed as a single piece and then encapsulated by the molding base.

10. A multilayer interconnection structure, comprising:
a frontside interconnection layer, comprising:
a frontside molding base;
two frontside conductive pillars formed within and extending through the frontside molding base; and
a frontside transverse block formed within and extending through the frontside molding base, and the frontside transverse block is between and connected to the two frontside conductive pillars; and
a backside interconnection layer laminated on the frontside interconnection layer, comprising:
a backside molding base; and
a backside conductive pillar formed within and extending through the backside molding base, and
wherein the backside conductive pillar is vertically aligned with and coupled to one of the two frontside conductive pillars and the transverse conductive block.

11. The multilayer interconnection structure of claim 10, further comprising:
two frontside conductive pads mounted on the frontside interconnection layer, wherein each of the two frontside conductive pads is vertically aligned with and connected to one of the two frontside conductive pillars; and
frontside conductive traces mounted on the frontside interconnection layer and between the two frontside conductive pads.

12. The multilayer interconnection structure of claim 10, wherein the transverse conductive block is integrally formed with the two frontside conductive pillars adjacent thereto as a single piece.
